(19) United States
(12) Patent Application Publication
(10) Pub. No.: US 2015/0008593 A1
(43) Pub. Date: Jan. 8, 2015

(54) STACKED SEMICONDUCTOR DEVICE AND METHOD FOR MANUFACTURING THE SAME

(71) Applicant: OLYMPUS CORPORATION, Tokyo (JP)

(72) Inventors: Yoshiaki Takemoto, Toyko (JP); Naohiro Takazawa, Toyko (JP); Hiroshi Kikuchi, Hidaka-shi (JP)

(73) Assignee: OLYMPUS CORPORATION, Tokyo (JP)

(21) Appl. No.: 14/491,520

(22) Filed: Sep. 19, 2014

Related U.S. Application Data
(63) Continuation of application No. PCT/JP2013/056864, filed on Mar. 12, 2013.

(30) Foreign Application Priority Data
Mar. 23, 2012 (JP) 2012-067963

(51) Int. Cl. H01L 23/00; H01L 21/56

(52) U.S. Cl. CPC H01L 24/32; H01L 24/83; H01L 21/56; H01L 2924/10253; H01L 2924/186; H01L 2224/32145; H01L 2224/8309; H01L 2224/8385
USPC 257/777; 438/109

(57) ABSTRACT

A stacked semiconductor device includes a first substrate and a second substrate. The first electrode is connected to the second electrode so that the first surface faces the second surface. A tip portion of the first wall section that faces the second substrate is connected to a tip portion of the second wall section that faces the first substrate. The first wall section is connected to the second wall section over an entire circumference. An outside space that is formed in an outside of the first wall section and an outside of the second wall section between the first substrate and the second substrate is filled with a sealing member over the entire circumference.

The present invention relates to a stacked semiconductor device and a method for manufacturing the same.

This application is a continuation application based on PCT/JP2013/056864, filed on Mar. 12, 2013, claiming priority based on Japanese Patent Application No. 2012-067963, filed in Japan on Mar. 23, 2012. The contents of both the Japanese Patent Application and the PCT Application are incorporated herein by reference.

### TECHNICAL FIELD

### Background Art

In semiconductor devices, a technique of increasing the degree of integration has constantly been advanced, and the degree of integration has thus far been enhanced, mainly, by the promotion of microfabrication of a circuit pattern. However, microfabrication itself has reached its limit. In order to further enhance the degree of integration, development from a related-art two-dimensional structure to a three-dimensional structure in which the configuration is made three-dimensional has been expected to be one solution.

If 3D-LSI is roughly classified, 3D-LSI can be classified into “simple chip stacking” of stacking only known good dies (KGDs) with a low-precision die bonder and connecting semiconductor chips to each other with a wire bond, “package type stacking” of stacking good packages subjected to a burn-in test, and “through-electrode type stacking (hereinafter referred to as through si via (TSV) stacking)” of providing through-electrodes or micro-bumps between elements on a wafer (substrate) made of silicon and directly connecting wafers or semiconductor chips.

The previous two kinds of stacking are already at the level of practical use, and the TSV stacking is expected as a final form. This is because, for example, in the case of DRAMs, capacity can be increased with no change in chip size or design line width by simple stacking of memory cell array wafers without waiting for advanced microfabrication.

Meanwhile, the TSV stacking is classified into the following three methods.

(1) Chip-to-Chip (C2C): this is a simple technique of stacking KGDs.

(2) Chip-to-Wafer (C2W): KGDs are mounted on a wafer, and this type can be said to be a system similar to (1).

(3) Wafer-to-Wafer (W2W): this is a type in which wafers are directly pasted together on the assumption that the yield of the wafers is high, and can be said to be a final stacking form.

The present invention relates to a W2W type bonding technique. A wafer-bonding apparatus that bonds wafers in that method is shown in FIGS. 11 and 12. In addition, the outline of the entire wafer-bonding apparatus is described in, for example, Japanese Unexamined Patent Application, First Publication No. 2005-251792 and this wafer-bonding apparatus is well-known. For this reason, the illustration and description of the wafer-bonding apparatus are omitted, and only a portion related to the present invention is shown and described.

Each of two wafers 151 and 152 is provided in an electrode region 154 where connection electrodes (electrodes) 153 are formed. The periphery of the electrode region 154 serves as a blank region where anything other than the wafer 151 or 152 is not provided at all. The connection electrodes 153 are formed on the wafers 151 and 152, respectively, in the electrode region 154 and the wafers 151 and 152 are electrically bonded by bonding the connection electrodes 153 formed on the wafer 151 and 152. In addition, dummy electrodes that do not contribute to electrical conduction and maintain the bonding strength may also be included in the connection electrodes 153.

In the W2W type, the wafers 151 and 152 are overlapped with each other and bond together so that the corresponding connection electrodes 153 between the wafers 151 and 152 come into contact with each other.

Specifically, the connection electrodes 153 of the wafers 151 and 152 are sandwiched between pressure plates 155 and 156 so as to come into contact with each other, and the pressure plates 155 and 156 are pressurized from the top and bottom by a pressing apparatus (not shown). Generally, the heating pressurizing bonding of heating, pressurizing, and bonding the connection electrodes 153, is used for the bonding the wafers 151 and 152.

In bonding such a W2W type, a bonding method that is different from the aforementioned Japanese Unexamined Patent Application, First Publication No. 2005-251792 is disclosed in Japanese Unexamined Patent Application, First Publication No. 2009-220151. That is, the bonding method of Japanese Unexamined Patent Application, First Publication No. 2009-220151, as shown in FIG. 11, provides an electrode structure in which the electrode region 154 formed from the plurality of connection electrodes 153 is surrounded by an outer peripheral connecting section (wall section) 157, thereby bringing a region surrounded by the outer periphery connecting section 157 into an arbitrary atmospheric condition, and uses a manufacturing process using temporary bonding and main bonding processes, thereby enhancing connection reliability.

In addition, a plurality of stacked semiconductor devices are formed by bonding the wafers 151 and 152.

### SUMMARY OF THE INVENTION

### Solution to Problem

A stacked semiconductor device of the present invention includes a first substrate which has a first electrode and a wall section that is provided to stand so as to surround the first electrode, the first electrode and the wall section being provided on a first surface; and a second substrate which has a second electrode that is provided on a second surface, wherein the first electrode is connected to the second electrode so that the first surface faces the second surface; the wall section is arranged at between the first substrate and the second substrate; and an inside space that is formed in an outside of the wall section between the first substrate and the second substrate is filled with a sealing member over the entire circumference.

Additionally, according to a second of the present invention, in the above stacked semiconductor device of the first aspect, the wall portion may include a first wall section that is provided on the first surface and is provided to stand so as to surround the first electrode, and a second wall section that is provided on the second surface and is provided to stand so as to surround the second electrode, a tip portion of the first wall section that faces the second substrate may be connected to a tip portion of the second wall section that faces the first substrate; the first wall section may be connected to the second wall section over an entire circumference; and an outside space that is formed in an outside of the first wall section and an outside of the second wall section between the first substrate and the second substrate may be filled with a sealing member over the entire circumference.

Additionally, according to a third of the present invention, in the above stacked semiconductor device of the first aspect, an inside space that is formed in an inside of the first wall section and the second wall section between the first substrate and the second substrate may be filled with nitrogen gas or rare gas or the space is decompressed so as to become a vacuum

Additionally, according to a fourth of the present invention, in the above stacked semiconductor device of the first aspect, the sealing member may be epoxy resin.

Additionally, according to a fifth aspect of the present invention, a method for manufacturing a stacked semiconductor device includes a connecting process of connecting a plurality of first electrodes to a plurality of second electrodes so that a first surface faces a second surface and connecting a tip portion of a plurality of first wall sections that face the second substrate to a tip portion of a plurality of second wall sections that face the first substrate, wherein the first substrate has the plurality of first electrodes and the plurality of first wall sections that are provided to stand so as to surround the a plurality of first electrodes, the plurality of first electrodes and the plurality of first wall sections are provided on the first surface, a second substrate has the plurality of second electrodes and the plurality of second wall sections that are provided to stand so as to surround the plurality of second electrodes, the plurality of second electrodes and the plurality of second wall sections are provided on the second surface, and the plurality of first wall sections are connected to the plurality of second wall sections over an entire circumference; a sealing process of filling a space that is formed in an outside of the plurality of first wall sections and an outside of the plurality of second wall sections between the first substrate and the second substrate with a sealing member; and a cutting process of cutting the first substrate, the second substrate, and the sealing member in the middle between the adjacent first wall sections when viewed in a thickness direction of the first substrate.

### BRIEF DESCRIPTION OF DRAWINGS

FIG. 1 is a cross-sectional view of a side surface of a stacked semiconductor device of a first embodiment of the present invention.

FIG. 2 is a cross-sectional view taken along cutting line A1-A1 in FIG. 1.

FIG. 3 is a cross-sectional view of a side surface in a state where both substrates before being cut are arranged to face each other.

FIG. 4 is a bottom plan view of main portions of a first substrate before being cut.

FIG. 5 is a cross-sectional view of a side surface illustrating a state when a connecting process of a method for manufacturing the stacked semiconductor device of the present embodiment is ended.

FIG. 6 is a cross-sectional view taken along cutting line A2-A2 in FIG. 5.

FIG. 7 is a cross-sectional view of a side surface of a stacked semiconductor device of a second embodiment of the present invention.

FIG. 8 is a cross-sectional view of a side surface in a state where both substrates before being cut are arranged to face each other.

FIG. 9 is a cross-sectional view of a side surface illustrating a state when a connecting process of a method for manufacturing the stacked semiconductor device of the present embodiment is ended.

FIG. 10 is a cross-sectional view of main portions in a stacked semiconductor device of the embodiment of a modification example of the present invention.

FIG. 11 is a plan view of a wafer used for a related-art wafer-bonding apparatus.

FIG. 12 is a schematic view illustrating a state where the wafer is bonded by the wafer-bonding apparatus.

### DESCRIPTION OF EMBODIMENTS

### First Embodiment

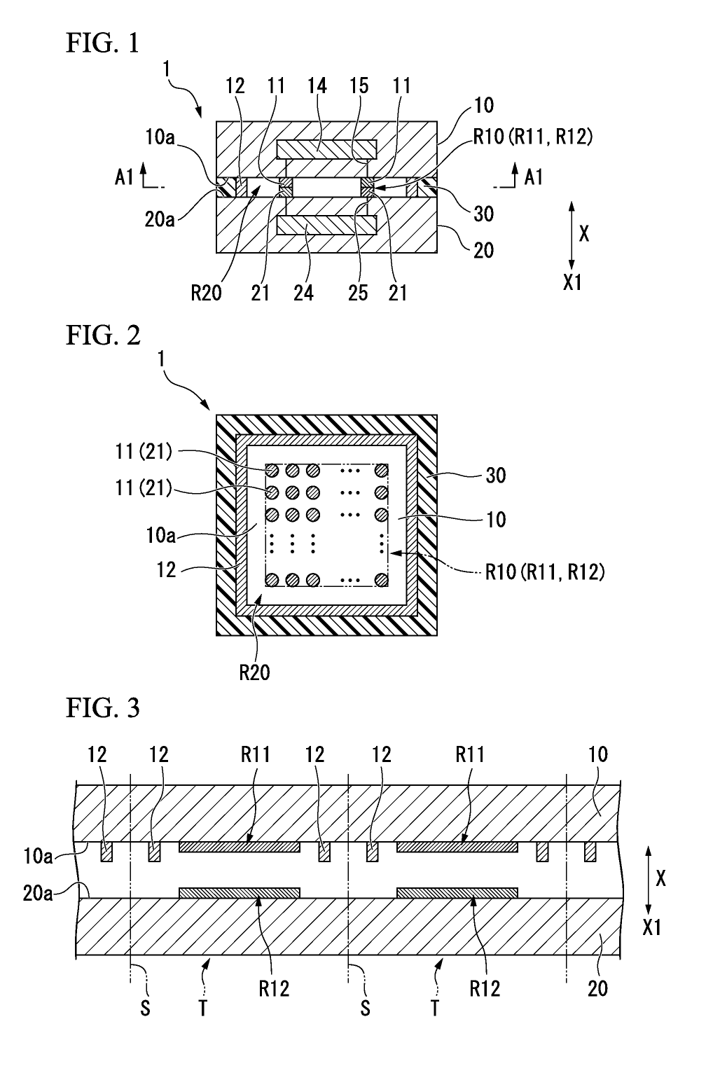

Hereinafter, a first embodiment of a stacked semiconductor device related to the present invention (hereinafter, simply referred to as a “semiconductor device”) will be described referring to FIGS. 1 to 6.

As shown in FIGS. 1 and 2, the semiconductor device 1 includes a first substrate 10 in which a plurality of first electrodes 11 and wall sections 12 erected so as to surround the plurality of first electrodes 11 are provided on first surface 10a, and a second substrate 20 in which a plurality of second electrodes 21 are provided on a second surface 20a.

In addition, elements 14 and 24 and wiring lines 15 and 25 to be described below are shown only in FIGS. 1 and 7 for convenience of description.

The first substrate 10 is formed of a material, such as silicon, in the shape of a rectangular flat plate when viewed in a thickness direction X of the first substrate 10. The element 14, such as a transistor, is displaced in the first substrate 10. A contact point (not shown) provided at the element 14 is connected to a first electrode 11 via a wiring line 15, such as a via.

The plurality of first electrodes 11 are arranged in a grid shape on first surface 10a, and the plurality of first electrodes 11 constitute a first electrode region R11 as a whole. In a plan view viewed in the thickness direction X, for example, each first electrode 11 is formed with a diameter of about several micrometers, and the first electrode region R11 is formed at about several millimeters square.

The wall sections 12 are formed in the shape of a rectangular shape (in a rectangular outline) in which the outer shape of the first electrode region R11 is enlarged outward and the first substrate 10 is diminished inward when viewed in the thickness direction X. An erection direction in which the wall sections 12 are erected from first surface 10a becomes one side X1 in the thickness direction X. The sum of the lengths of the first electrode 11 and the second electrode 21 in the thickness direction X is set to be approximately equal to the length of the wall sections 12 in the thickness direction X. In this example, the wall sections 12 are formed of the same metal as the first electrode 11, for example, copper, gold, or the like.

The second substrate 20 is formed of a material, such as silicon, in the shape of a flat plate that is the same shape as the first substrate 10 when viewed in the thickness direction X. The same element 24 as the element 14 is built in the second substrate 20. A contact point (not shown) provided on the element 24 is connected to a second electrode 21 via a wiring line 25.

The plurality of second electrodes 21 are arranged in the same grid shape as the plurality of first electrodes 11 on the second surface 20a, and the plurality of second electrodes 21 constitute a second electrode region R12 as a whole.

The first electrode 11 is connected to the second electrode 12 so that the first surface 10a of the first substrate 10 faces the second surface 20a of the second substrate 20. A tip portion of the wall section 12 on the one side X1 that faces the second substrate 20 is connected to the second surface 20a over an entire circumference. The first electrode 11 and the second electrode 21 are electrically connected to each other by pressing both of the electrodes 11 and 21 in a heated state. The second substrate 20 and the wall sections 12 are similarly connected to each other.

An outside space that is formed in an outside of the wall sections 12 between the first substrate 10 and the second substrate 20 is filled with epoxy resin (sealing member) 30 over the entire circumference. An internal space (inside space) R20 inside the wall sections 12 between the first substrate 10 and the second substrate 20 is airtightly sealed from the outside by connecting the second substrate 20 and the wall sections 12 to each other and tilling with the epoxy resin 30.

In this example, the internal space R20 is decompressed so as to become a vacuum. Here, the term “vacuum” means a pressure lower than the atmospheric pressure, and is preferably 0 Pa or higher and 1 Pa or lower in absolute pressure. Accordingly, peripheries of the electrodes 11 and 21 are brought into a vacuum atmosphere.

An electrode region R10 is constituted by the first electrode region R11 and the second electrode region R12. Hereinafter, in respective drawings, the electrode region R10 is shown by the same hatching.

The semiconductor device 1 is configured so as to perform predetermined processing while the elements 14 and 24 electrically connected to each other via the wiring lines 15 and 25 and the electrodes 11 and 21 mutually transmit and receive signals.

Next, a method for manufacturing the semiconductor device 1 of the present embodiment, in which the semiconductor device 1 configured as described above is manufactured, will be described.

The present manufacturing method includes a connecting process of connecting the first substrate 10 and the second substrate 20 to each other, a sealing process of pouring a space between the first substrate 10 and the second substrate 20 with the epoxy resin 30, and a cutting process of cutting the substrates 10 and 20.

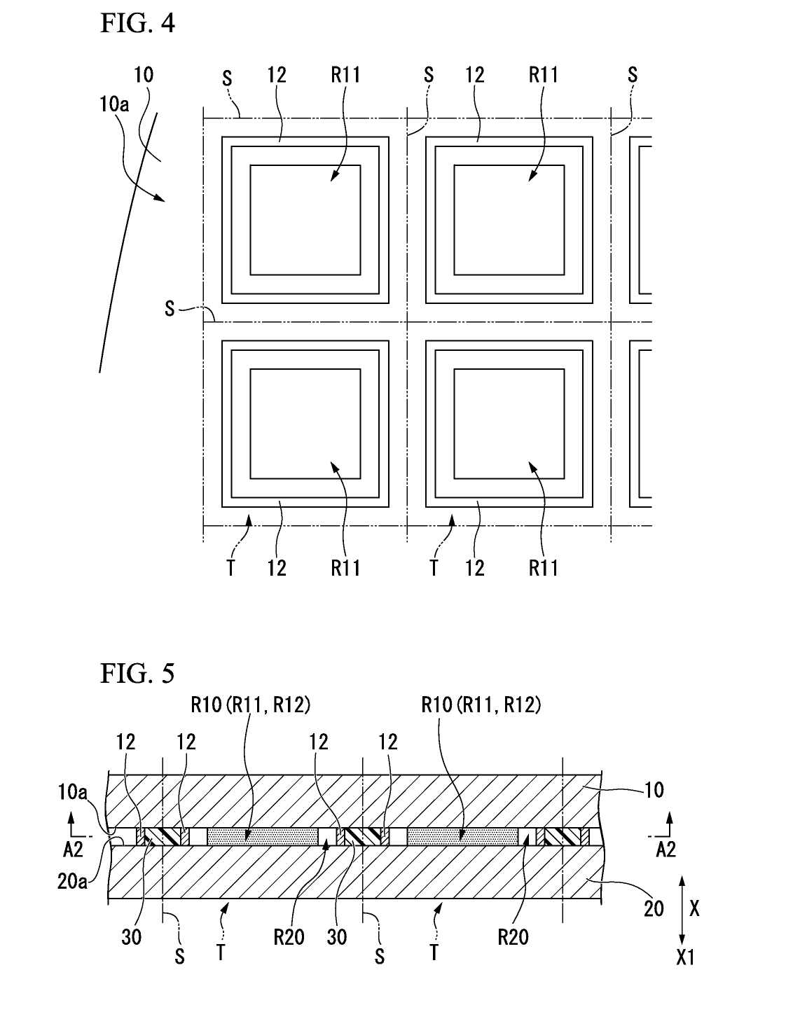

As shown in FIGS. 3 and 4, the substrates 10 and 20 that are substantially circular when viewed in the thickness direction X are used for the present manufacturing method. Then, as will be described below, in the cutting process, the substrates 10 and 20 are cut at scribe lines (cutting lines) S, and are cut into rectangular individual regions T in a plan view and are thereby cut (individualized) into individual semiconductor devices 1.

In this way, in the substrates 10 and 20 that are substantially circular, a plurality of individual regions T are arranged substantially in the shape of a grid.

The first electrode region R11 is constructed in advance by forming the element 14 and the wiring lines 15 on each individual region T of the first substrate 10 and providing the first electrodes 11 connected to the wiring lines 15, respectively, on the first surface 10a of the first substrate 10. Then, the wall sections 12 are formed on each individual region T so as to surround the first electrode region R11. In addition, in this example, the first electrodes 11 and the wall sections 12 are formed of metal on the first surface 10a. Therefore, the first electrodes 11 and the wall sections 12 can be formed by the same semiconductor manufacturing process.

Similarly, the second electrode region R12 is constructed by forming the element 24 and the wiring lines 25 on each individual region T of the second substrate 20 and providing the second electrodes 21 connected to the wiring lines 25, respectively, on the second surface 20a of the second substrate 20.

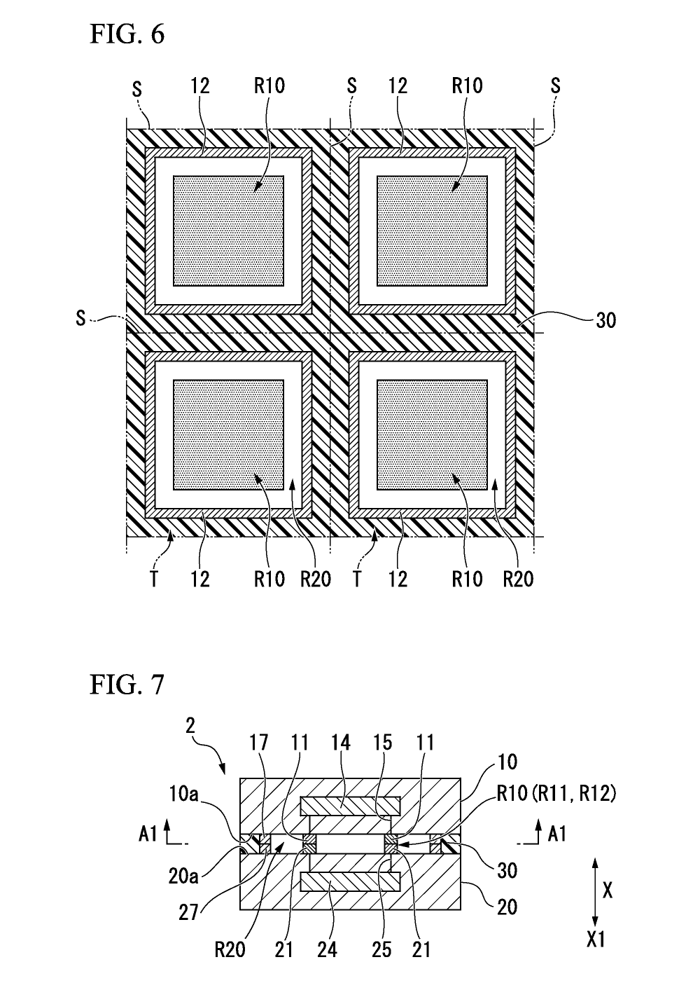

First, in the connecting process, the following processes are performed within a vacuum chamber (not shown). As shown in FIGS. 5 and 6, as for the first substrate 10 and the second substrate 20, the first surface 10a and the second surface 20a are made to face each other, each of the first electrodes 11 of the first electrode region R11 and each of the second electrode 21 of the second electrode region R12 are connected to each other, and the tip portion of each of the wall sections 12 on the one side X1 is connected to the second surface 20a over its entire circumference. Accordingly, the first substrate 10 and the second substrate 20 are connected to each other.

Specifically, although not shown, the first electrodes 11 and the second electrodes 21 are bonded together and the wall sections 12 and the second substrate 20 are bonded together by arranging the substrates 10 and 20 between a pair of pressure plates of a well-known pressure apparatus and by pressing the substrates 10 and 20 in the thickness direction X with the pair of pressure plates in a state where each first electrode 11 and each second electrode 21 brought into contact with each other are heated by a heating apparatus (not shown) and the wall sections 12 and the second substrate 20 brought into contact with each other are heated by the heating apparatus.

Next, in the sealing process, the epoxy resin 30 that is heated and has enhanced flowability is poured into the outside of each wall section 12 between the first substrate 10 and the second substrate 20 that are connected to each other. Since the wall section 12 and the second substrate 20 are connected to each other over the entire circumference, the epoxy resin 30 does not flow into the internal space R20. Additionally, since the epoxy resin 30 is poured in a vacuum atmosphere, mixing of gas into the epoxy resin 30 can he suppressed, and the space between the substrates 10 and 20 can be easily filled with the epoxy resin 30.

Thereafter, the heated epoxy resin 30 is cooled and hardened.

Subsequently, in the cutting process, the first substrate 10, the second substrate 20, and the epoxy resin 30 are cut by dicing or the like at the scribe lines S shown in FIGS. 5 and 6. Each scribe line S is set at an intermediate portion between the adjacent wall sections 12 when viewed in the thickness direction X. That is, the epoxy resin 30 is cut so as to be disposed over the entire circumference between a cutting plane of the first substrate 10 and a cutting plane of the second substrate 20.

Since the space between the first substrate 10 and the second substrate 20 is filled with the epoxy resin 30, the load acting when the substrates 10 and 20 are cut can be supported by the epoxy resin 30, and an excessive load (shock) can be prevented from acting on a bonding portion between each first electrode 11 and each second electrode 21 and a bonding portion between each wall section 12 and the second substrate 20.

The substrates are cut and individualized at the scribe lines S, whereby the semiconductor devices 1 are obtained.

The semiconductor device 1 is manufactured by the processes from the connecting process to the cutting process which have been described up to now.

As described above, according to the semiconductor device 1 and the method for manufacturing the semiconductor device 1 in the present embodiment, the second substrate 20 and the wall section 12 are connected to each other over the entire circumferences of the wall section 12 and the epoxy resin 30 is poured, so that the internal space R20 inside the wall section 12 can be airtightly maintained and a connected state between both the electrodes 11 and 21 can be stabilized.

Since the epoxy resin 30 is poured outside the wall section 12 between the first substrate 10 and the second substrate 20, the epoxy resin 30 supports the load acting when the substrates 10 and 20 are cut. Accordingly, when the substrates 10 and 20 are individualized to manufacture the semiconductor devices 1, an excessive load can be prevented from acting on connecting sections between the wall section 12 and the second substrate 20, and the connection between the electrodes 11 and 21 can be ensured.

Since the internal space R20 is decompressed so as to become a vacuum, influence, such as oxidization or the like, on the electrodes 11 and 21 according to the atmosphere can be suppressed, and the connection reliability between the electrodes 11 and 21 can be ensured.

Since the viscosity of the epoxy resin 30 when heated and enhanced in flowability is relatively lower than the viscosity of other resins, the space between the first substrate 10 and the second substrate 20 can be easily filled with the epoxy resin 30.

### Second Embodiment

Next, although a second embodiment of the present invention will be described referring to FIGS. 7 to 9, the same parts as the above embodiment will be designated by the same reference numerals and the description thereof will be omitted, and only points of difference will be described.

In the semiconductor device 1 of the first embodiment, the wall section is formed only on first surface 10a of the first substrate 10. However, in a semiconductor device 2 of the present embodiment shown in FIG. 7, this wall section is formed on each of the first surface 10a of the first substrate 10 and the second surface 20a of the second substrate 20. That is, in the semiconductor device 2, a first wall section 17 erected 10 so as to surround the plurality of first electrodes 11 is provided on the first surface 10a of the first substrate instead of the wall section 12 of the semiconductor device 1, and a second wail section 27 erected so as to surround the plurality of second electrodes 21 is provided on the second surface 20a of the second substrate 20.

The first wall section 17 is different from the wall section 12 of the first embodiment only in thickness (the length in the thickness direction X). The thickness of the first wall section 17 is equal to the thickness of each first electrode 11. Additionally, the first wall section 17 is formed of the same metal as the first electrode 11. By adopting this configuration, each first electrode 11 and the first wall section 17 can be more easily formed by the same semiconductor manufacturing process.

Similarly, the thickness of the second wall section 27 is equal to the thickness of each second electrode 21. The first wall section 17 and the second wall section 27 are formed so as to overlap each other (in the same shape) when viewed in the thickness direction X.

The first electrode 11 is connected to the second electrode 21 so that the first surface 10a of the first substrate 10 faces the second surface 20a of the second substrate 20. A tip portion of the first wall section 17 that faces the second substrate 20 is connected to a tip portion of the second wall section 27 that faces the first substrate 10. The first wall section 17 is connected to the second wall section 27 over an entire circumference. The first wall section 17 and the second wall section 27 are connected to each other by pressing, in a state where both the wall sections 17 and 27 are heated.

In this embodiment, an outside space that is formed in an outside of the first wall section 17 and an outside of the second wall section 27 between the first substrate 10 and the second substrate 20 is filled with the aforementioned epoxy resin 30 (sealing member) over the entire circumference.

Next, a method for manufacturing the semiconductor device 2 of the present embodiment, in which the semiconductor device 2 configured as described above is manufactured, will be described.

The manufacturing method of the present embodiment includes the connecting process, the sealing process, and the cutting process, similar to the manufacturing method of the first embodiment.

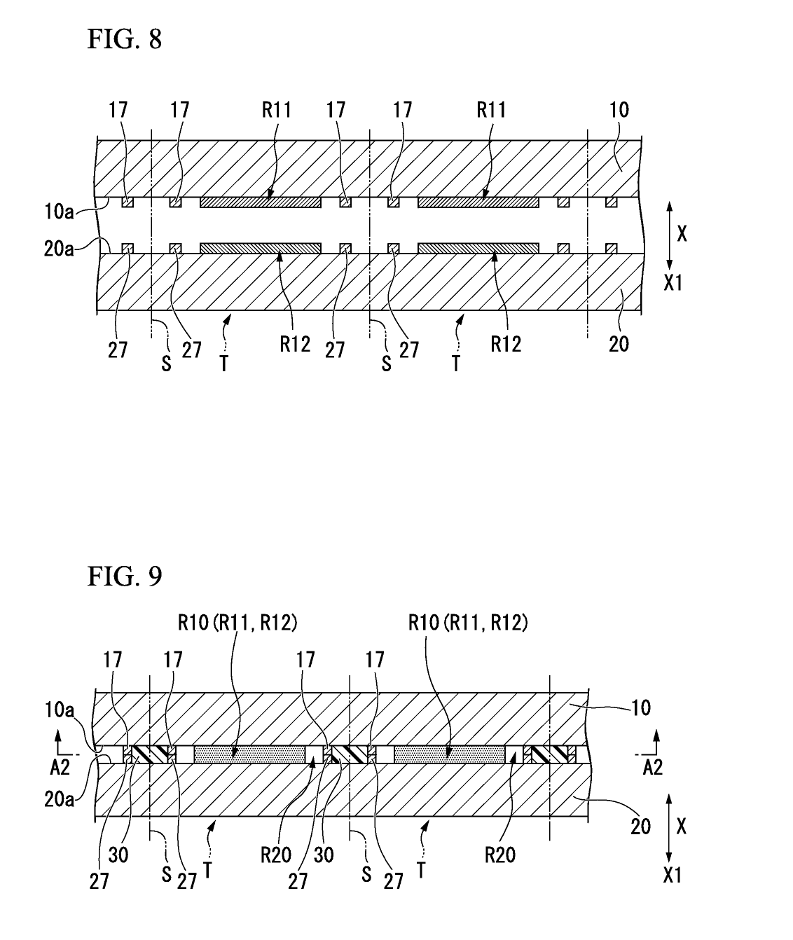

In advance, as shown in FIG. 8, the first electrode region R11 including the plurality of first electrodes 11 and the first wall sections 17 provided so as to surround the first electrode region R11 are formed in each individual region T of the first substrate 10. Since the thickness and material of the plurality of first electrodes 11 and the first wall sections 17 are as mentioned above. the plurality of first electrodes 11 and the first wall sections 17 can be more easily formed by the same semiconductor manufacturing process.

Similarly, the second electrode region R12 including the plurality of second electrodes 21 and the second wall section 27 provided so as to surround the second electrode region R12 are formed in each individual region T of the second substrate 20.

First, in the connecting process, as shown in FIG. 9, as for the first substrate 10 and the second substrate 20, the first surface 10a and the second surface 20a are made to face each other, each of the first electrode 11 of the first electrode region R11 and each of the second electrodes 21 of the second electrode region R12 are connected to each other, and the tip portion of each of the first wall sections 17 from which the first wall section 17 is erected and the tip portion of each of the second wall sections 27 from which the second wall section 27 are erected are connected to each other over the entire circumference of the first wall section 17. Accordingly, the first substrate 10 and the second substrate 20 are connected to each other.

Next, in the sealing process, the epoxy resin 30 is poured outside each of the first wall sections 17 and each of the second wall sections 27 between the first substrate 10 and the second substrate 10.

Subsequently, in the cutting process, the first substrate 10, the second substrate 20, and the epoxy resin 30 are cut at the scribe lines S shown in FIG. 9. Each scribe line S is set at an intermediate portion between the adjacent first wall sections 17 when viewed in the thickness direction X.

The semiconductor device 2 is manufactured by the processes from the connecting process to the cutting process which have been described up to now.

As described above, according to the semiconductor device 2 and the method for manufacturing the semiconductor device 2 in the present embodiment, the connection reliability between the electrodes 11 and 21 of the substrates 10 and 20 can be ensured even when the substrates are individualized.

The present embodiment may be configured so that the thickness of the first wall section 17 is not equal to the thickness of each first electrode 11 and the thickness of the second wall section 27 is not equal to the thickness of each second electrode 21. This is because the first substrate 10 and the second substrate 20 are extremely well connected if the sum of the thickness of the first wall section 17 and the thickness of the second wall section 27 and the sum of the thickness of the first electrode 11 and the thickness of the second electrode 21 are approximately equal to each other.

Although the first and second embodiments of the present invention have been described above in detail with reference to the drawings, the specific configuration is not limited to the embodiments, and changes to the configuration are also included without departing from the scope of the present invention.

For example, in the first and second embodiments, the epoxy resin is used as the sealing member. However, the sealing member is not limited to this, and thermoplastic resin, thermosetting resin, an organic material, or the like can be appropriately selected and used in addition to this. However, it is preferable that the sealing member be a sealing member of which the viscosity becomes low when being heated and having flowability. This is because the space between the first substrate 10 and the second substrate 20 can be filled with the sealing member without a gap.

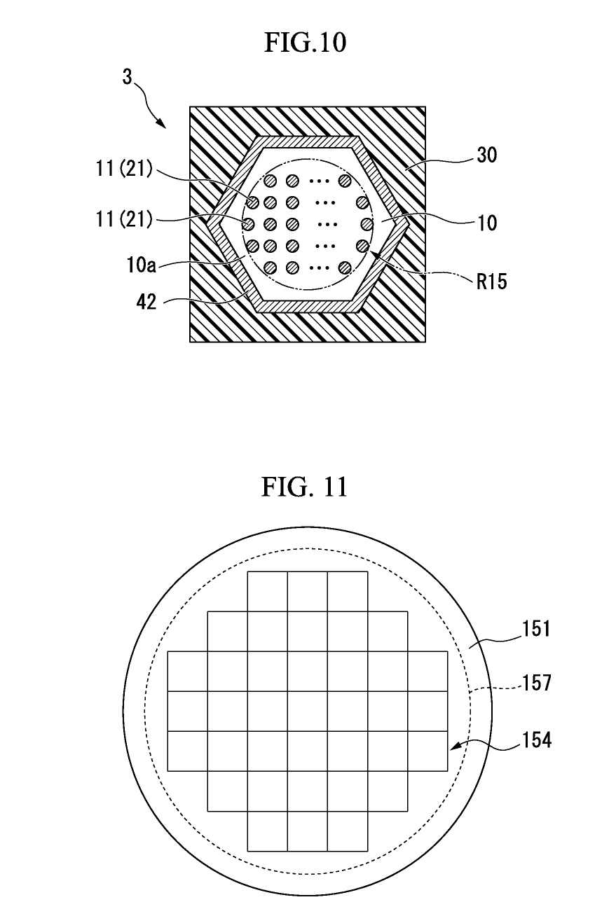

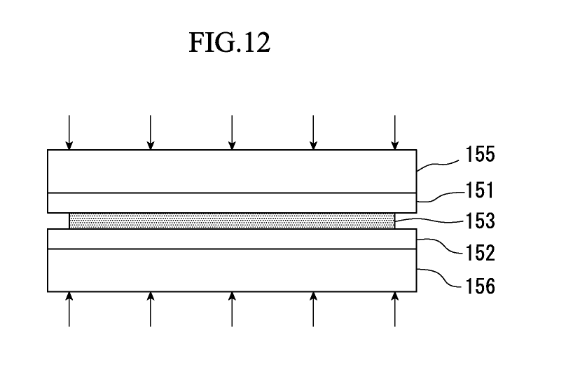

The wall sections 12, 17, and 27 are formed in a rectangular shape when viewed in the thickness direction X. However, the shape of the wall sections is not limited to this. As in a semiconductor device 3 shown in FIG. 10, a wall section 42 may be formed in a polygonal shape, such as a hexagonal shape, other than the rectangular shape, or may be formed in a round shape or an elliptical shape.

The shape of the first electrode region R11 constituted by the plurality of first electrodes 11 may also be formed in a round shape or an elliptical shape, or may be formed in a polygonal shape. The same also applies to the second electrode region R12.

In the first and second embodiments, the internal space R20 is decompressed so as to become a vacuum. However, the internal space may be configured so as to be filled with nitrogen gas or rare gases. The term “rare gases” means helium gas, neon gas, argon gas, krypton gas, xenon gas, and radon gas. Even if such a configuration is adopted, influence, such as oxidization or the like, on the electrodes 11 and 21 according to the atmosphere can be suppressed, and the connection reliability between the electrode 11 and 21 can be ensured.

Although the wall sections 12, 17, and 27 are formed of the same metal as the first electrode 11, the wall sections 12, 17, and 27 may be formed of resin or the like.

Additionally, although the wall section 12 is formed so as to surround the plurality of first electrodes 11, there is no limit to the number of the first electrodes 11 that the wall section 12 surrounds, and any number of first electrodes may be used if one or more of the first electrodes are included. This also applies to the wall sections 17 and 27.

### REFERENCE SIGNS LIST

1, 2, 3: SEMICONDUCTOR DEVICE (STACKED SEMICONDUCTOR DEVICE)
10: FIRST SUBSTRATE
10a: FIRST SURFACE
11: FIRST ELECTRODE
12, 42: WALL SECTION
17: FIRST WALL SECTION
20: SECOND SUBSTRATE
20a: SECOND SURFACE
21: SECOND ELECTRODE
27: SECOND WALL SECTION
30: EPOXY RESIN (SEALING MEMBER)
X: THICKNESS DIRECTION

1. A stacked semiconductor device, comprising:
a first substrate which has a first electrode and a wall section that is provided to stand so as to surround the first electrode, the first electrode and the wall section being provided on a first surface; and
a second substrate which has a second electrode that is provided on a second surface,
wherein the first electrode is connected to the second electrode so that the first surface faces the second surface;
the wall section is arranged at between the first substrate and the second substrate; and
an inside space that is formed in an outside of the wall section between the first substrate and the second substrate is filled with a sealing member over the entire circumference.

2. The stacked semiconductor device according to claim 1,
wherein the wall portion includes a first wall section that is provided on the first surface and is provided to stand so as to surround the first electrode; and a second wall section that is provided on the second surface and is provided to stand so as to surround the second electrode,
a tip portion of the first wall section that faces the second substrate is connected to a tip portion of the second wall section that faces the first substrate;
the first wall section is connected to the second wall section over an entire circumference; and
an outside space that is formed in an outside of the first wall section and an outside of the second wall section between the first substrate and the second substrate is filled with a sealing member over the entire circumference.

3. The stacked semiconductor device according to claim 1,
wherein an inside space that is formed in an inside of the first wall section and the second wall section between the first substrate and the second substrate is filled with nitrogen gas or rare gas or the space is decompressed so as to become a vacuum.

4. The stacked semiconductor device according to claim 1,
wherein the sealing member is epoxy resin.

5. A method for manufacturing a stacked semiconductor device comprising:
a connecting process of connecting a plurality of first electrodes to a plurality of second electrodes so that a first surface faces a second surface and connecting a tip portion of a plurality of first wall sections that face the second substrate to a tip portion of a plurality of second wall sections that face the first substrate, wherein the first substrate has the plurality of first electrodes and the plurality of first wall sections that are provided to stand so as to surround the a plurality of first electrodes, the plurality of first electrodes and the plurality of first wall sections are provided on the first surface, a second substrate has the plurality of second electrodes and the plurality of second wall sections that are provided to stand so as to surround the plurality of second electrodes, the plurality of second electrodes and the plurality of second wall sections are provided on the second surface, and the plurality of first wall sections are connected to the plurality of second wall sections over an entire circumference;
a sealing process of filling a space that is formed in an outside of the plurality of first wall sections and an outside of the plurality of second wall sections between the first substrate and the second substrate with a sealing member; and
a cutting process of cutting the first substrate, the second substrate, and the sealing member in the middle between the adjacent first wall sections when viewed in a thickness direction of the first substrate.
